(19) United States
(12) Patent Application Publication
(10) Pub. No.: US 2026/0287345 A1
(43) Pub. Date: Sep. 24, 2026

(54) METHOD OF DETERMINING MISALIGNMENT OF SEMICONDUCTOR DEVICE

(71) Applicant: SK hynix Inc., Gyeonggi-do (KR)

(72) Inventors: Heon Yong CHANG, Gyeonggi-do (KR); Byung In KANG, Gyeonggi-do (KR); Myoung Hoon KWON, Gyeonggi-do (KR); Dong Seob YUN, Gyeonggi-do (KR)

(21) Appl. No.: 19/275,982

(22) Filed: Jul. 22, 2025

(30) Foreign Application Priority Data
Mar. 21, 2025 (KR) 10-2025-0036531

(51) Int. Cl. G01B 21/24; G01B 21/16

(52) U.S. Cl. CPC G01B 21/24; G01B 21/16; G01B 2210/56

(57) ABSTRACT

According to embodiments of the present disclosure, a method of determining a misalignment of a semiconductor device including contacts arranged in a first direction and a second direction intersecting the first direction, and wirings connected to at least one of the contacts and spaced apart from each other in the first direction may include measuring a first spacing between a first contact and a second contact neighboring each other in the first direction among the contacts, measuring a second spacing between a side surface of a first wiring among the wirings and a side surface of the first contact, wherein the first wiring is connected to the first contact, and determining whether there is a misalignment based on the first spacing and the second spacing.

### CROSS-REFERENCE TO RELATED APPLICATION

The present application claims priority under 35 U.S.C. §119(a) to Korean Patent Application No. 10-2025-0036531 filed on Mar. 21, 2025, which is incorporated herein by reference in its entirety.

### BACKGROUND

### Technical Field

Embodiments of the present disclosure relate to a method of determining a misalignment of a semiconductor device.

### Related Art

Memory devices are attracting attention as an important element in the electronics industry due to their characteristics such as miniaturization, multifunctionality and/or low manufacturing cost. As the electronics industry advances, memory devices are becoming more highly integrated, and the difficulty of forming various wirings and elements included in memory devices is increasing. For example, as the size of various wirings included in memory devices decreases and the distance between wirings decreases, a concomitant increase in defects such as interference between wirings has been observed.

### SUMMARY

Embodiments of the present disclosure are directed to providing a method of determining a misalignment of a semiconductor device. The embodiments provide a capability of accurately identifying the cause of the misalignment between neighboring wirings.

Objects of embodiments of the disclosure are not limited to those set forth herein, and other unmentioned objects would be apparent to one of ordinary skill in the art from the following description.

In an embodiment, a method of determining a misalignment of a semiconductor device including contacts arranged in a first direction and a second direction intersecting the first direction, and wirings connected to at least one of the contacts and spaced apart from each other in the first direction may include measuring a first spacing between a first contact and a second contact neighboring each other in the first direction among the contacts, measuring a second spacing between a side surface of a first wiring among the wirings and a side surface of the first contact, wherein the first wiring is connected to the first contact, and determining whether there is a misalignment based on the first spacing and the second spacing.

In an embodiment, a method of determining a misalignment of a semiconductor device including a first contact and a second contact, disposed spaced apart from each other by a first spacing in a first direction and a first wiring connected to the first contact, the first wiring having side surfaces facing each other in the first direction may include measuring a second spacing between a side surface among the side surfaces of the first wiring that is farther away from the first contact and a side surface of the first contact, and determining whether there is a misalignment based on the first spacing and the second spacing.

According to embodiments of the present disclosure, a capability of determining a misalignment of a semiconductor device and of accurately identifying the cause of the misalignment between neighboring wirings and/or contacts is provided.

The effects of the disclosure are not limited to the foregoing objects, and other effects will be apparent to one of ordinary skill in the art from the following detailed description.

### BRIEF DESCRIPTION OF THE DRAWINGS

The disclosure will be more fully understood from the following detailed description and the accompanying drawings, which are provided for illustration only and are not intended to limit the disclosure.

FIG. 1 is a flowchart showing an example of a method of determining a misalignment of a semiconductor device, in accordance with an embodiment of the present disclosure.

FIG. 2 is a flowchart showing an example of a misalignment determination step of FIG. 1, in accordance with an embodiment of the present disclosure.

FIG. 3 is a flowchart showing another example of the misalignment determination step of FIG. 1, in accordance with an embodiment of the present disclosure.

FIG. 4 is a view illustrating a planar structure of a semiconductor device, in accordance with an embodiment of the present disclosure.

FIG. 5 to FIG. 7 are views illustrating examples of the cross-sectional structure of a part indicated by a line I-I' of FIG. 4, in accordance with embodiments of the present disclosure.

FIG. 8 is a view illustrating an example of a semiconductor device, in accordance with an embodiment of the present disclosure.

### DETAILED DESCRIPTION

Hereinafter, embodiments of the present disclosure will be described in detail with reference to the accompanying drawings. In the following description, the same elements will be designated by the same reference numerals although they are shown in different drawings. Further, in the following description of the present disclosure, a detailed description of known functions and configurations incorporated herein will be omitted when it may make the subject matter of the present disclosure rather unclear. It is to be noticed that the terms “comprising,” “having,” “including” and so on, used in the description and claims, should not be interpreted as being restricted to the means listed thereafter unless specifically stated otherwise. Where an indefinite or definite article is used when referring to a singular noun, e.g., “a,” “an” and “the,” this may include a plural of that noun unless specifically stated otherwise.

Also, in describing the components of the disclosure, there may be terms used like first, second, A, B, (a), and (b). These are solely for the purpose of differentiating one component from another component but do not limit the substances, order, sequence or number of the components.

When it is mentioned that a first element "is connected or coupled to," “contacts or overlaps,” etc. a second element, it should be interpreted that not only can the first element “be directly connected or coupled to” or “directly contact or overlap” the second element, but a third element can also be "interposed" between the first and second elements or the first and second elements can "be connected or coupled to," “contact or overlap,” etc. each other via a fourth element. Here, another component may be included in at least one of the at least two components which are “connected,” “coupled” or “linked” with each other.

In descriptions for time flow relationships of components, an operating method or a fabricating method, in the case where pre and post relationships in terms of time or pre and post relationships in terms of flow are described, for example, by “after,” “following,” “next” or “before,” non-continuous cases may be included unless “immediately” or “directly” is used.

In the case where a numerical value for a component or its corresponding information (e.g., a level, etc.) is mentioned, even though there is no separate explicit description, the numerical value or its corresponding information can be interpreted as including an error range that may be caused by various factors (for example, a process variable, an internal or external shock, noise, etc.).

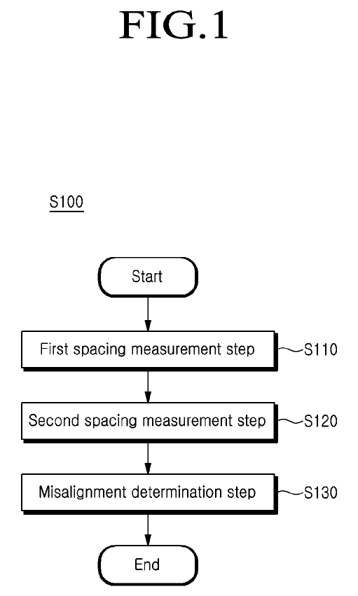

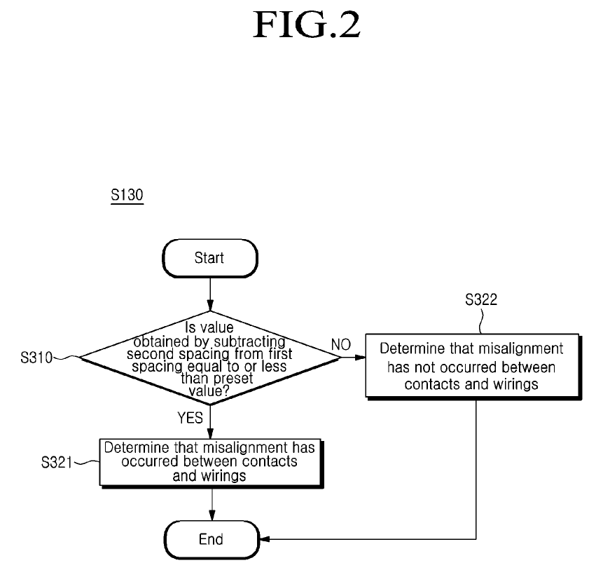

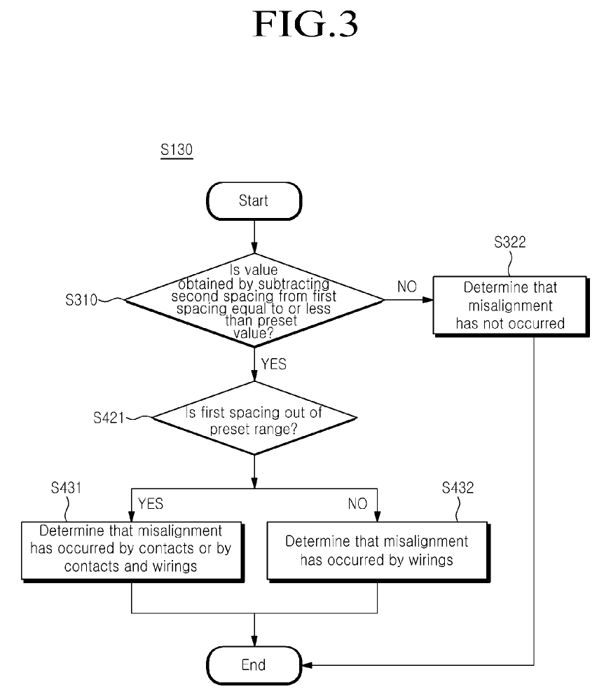

FIG. 1 is a flowchart showing an example of a method of determining a misalignment of a semiconductor device according to embodiments of the present disclosure. FIG. 2 is a flowchart showing an example of a misalignment determination step of FIG. 1. FIG. 3 is a flowchart showing another example of the misalignment determination step of FIG. 1.

Referring to FIG. 1, a method S100 of determining a misalignment of a semiconductor device according to embodiments of the present disclosure may include a first spacing measurement step S110, a second spacing measurement step S120 and a misalignment determination step S130. The second spacing measurement step S120 may be performed after the first spacing measurement step S110, but is not limited thereto. The second spacing measurement step S120 may be performed before the first spacing measurement step S110, or may be performed at the same stage as the first spacing measurement step S110.

A semiconductor device according to embodiments of the present disclosure may include contacts and wirings that are connected to one or more of the contacts and are spaced apart from each other. In the present specification, the contacts may mean structures that extend in one direction (for example, a vertical direction) to connect structures disposed at different locations (for example, different layers). In an embodiment, the contacts may be pillars that have a circular or elliptical cross-section. The wirings may extend in one direction. In an embodiment, each of the wirings may be connected to at least one of the contacts.

In an embodiment according to the present disclosure, the method S100 of determining a misalignment of a semiconductor device may include determining whether there is a misalignment between the contacts and the wirings included in the semiconductor device. For example, in the semiconductor device, the wirings may be disposed to be connected to the contacts after the contacts are arranged. The wirings may be aligned on the basis of locations where the contacts are arranged. When the spacing between the contacts is not matched to the spacing of the wirings, for example, too narrow or too wide, a misalignment between the wirings and the contacts may occur. Even in instances in which the spacing between the contacts is formed appropriately, a defect(s) may occur during the process of aligning the wirings, causing misalignment between the wirings and the contacts.

The method S100 of determining a misalignment of a semiconductor device according to the embodiments of the present disclosure may determine whether there is a misalignment between the contacts and the wirings that occurs during the process of forming the semiconductor device and the cause of the misalignment.

The first spacing measurement step S110 may include measuring a first spacing between a first contact and a second contact that neighbor each other among the contacts. The first contact and the second contact may be different contacts that are included in the contacts.

In an embodiment, the first spacing between the first contact and the second contact may be the minimum distance from a side surface of the first contact to a side surface of the second contact. For example, the first spacing may be the minimum length of a line segment that connects a point on the side surface of the first contact and a point on the side surface of the second contact. For example, the first spacing may be the distance between the upper surface of the first contact and the upper surface of the second contact.

The second spacing measurement step S120 may include measuring a second spacing between a side surface of a first wiring connected to the first contact among the wirings and the side surface of the first contact. The first wiring may be any one wiring that is included in the wirings.

In an embodiment, the second spacing may be the minimum distance between a side surface among side surfaces of the first wiring that is farther away from the first contact connected to the first wiring and the side surface of the first contact. For example, when one of side surfaces of the first wiring is disposed to overlap the first contact, the second spacing may be the minimum distance between a side surface among the side surfaces of the first wiring that does not overlap the first contact and the side surface of the first contact. Alternatively, when the first contact is located between side surfaces of the first wiring, the second spacing may be the minimum distance between a side surface among the side surfaces of the first wiring that is farther away from the first contact and the side surface of the first contact.

In the misalignment determination step S130, a misalignment may be determined by subtracting the second spacing from the first spacing to obtain a value (that may reflect a degree of misalignment).

Referring to FIG. 2, in an embodiment, the misalignment determination step S130 may include a step S310 of checking whether the value obtained by subtracting the second spacing from the first spacing is less than or equal to a preset value. When it is checked that the value obtained by subtracting the second spacing from the first spacing is less than or equal to the preset value (i.e., S310 - YES), it may be determined that a misalignment has occurred between the contacts and the wirings (S321). In contrast, when it is checked that the value obtained by subtracting the second spacing from the first spacing is greater than the preset value (i.e., S310 - NO), it may be determined that a misalignment has not occurred between the contacts and the wirings (S322).

Referring to FIG. 3, in an embodiment, the misalignment determination step S130 may include a step S310 of checking whether the value obtained by subtracting the second spacing from the first spacing is less than or equal to a preset value and a step S421 of checking whether the first spacing is out of a preset range. When it is checked that the value obtained by subtracting the second spacing from the first spacing is less than or equal to the preset value and the first spacing is out of the preset range (i.e., S421 - YES), it may be determined that a misalignment has occurred (for example, been caused) by the contacts or by both the contacts and the wirings (S431). In contrast, when it is checked that the value obtained by subtracting the second spacing from the first spacing is less than or equal to the preset value and the first spacing is within the preset range (i.e., S421 - NO), it may be determined that a misalignment has occurred (for example, been caused) by the wirings (S432). When the value obtained by subtracting the second spacing from the first spacing is greater than the preset value (i.e., S310 - NO), it may be determined that a misalignment has not occurred (S322).

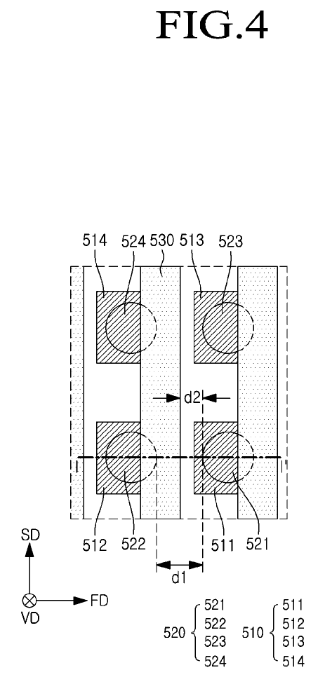

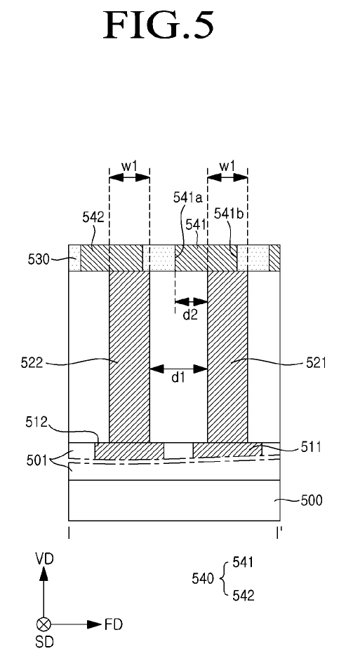

FIG. 4 is a view illustrating an example of the planar structure of a semiconductor device according to embodiments of the present disclosure. FIG. 5 to FIG. 7 are views illustrating examples of the cross-sectional structure of a part indicated by a line I-I' of FIG. 4.

In the accompanying drawings, two directions that are parallel to the upper surface of a substrate are defined as a first direction FD and a second direction SD, respectively, and a direction that vertically protrudes from the upper surface of the substrate is defined as a third direction VD. The first direction FD and the second direction SD may be substantially perpendicular to each other. The third direction VD is a direction that is perpendicular to the first direction FD and the second direction SD (for example, in a manner that the three directions form a three-dimensional (3D) axis). In the following description, the term ‘vertical’ or ‘vertical direction’ will be used as substantially the same meaning as the third direction VD. In the drawings, a direction indicated by an arrow and a direction opposite thereto represent the same direction (i.e., are along a same axis).

Referring to FIG. 4 and FIG. 5, the semiconductor device may include a substrate 500, an interlayer insulating layer 501 on the substrate 500, landing pads 510, contacts 520, an insulating layer 530, and wirings 540. The landing pads 510 may include a first landing pad 511, a second landing pad 512, a third landing pad 513 and a fourth landing pad 514. The contacts 520 may include a first contact 521, a second contact 522, a third contact 523 and a fourth contact 524.

The landing pads 510 may be arranged in the first direction FD and the second direction SD. The landing pads 510 may be disposed to be spaced apart from each other in the first direction FD and the second direction SD.

The contacts 520 may be disposed on the landing pads 510. Each of the contacts 520 may be disposed to correspond to one of the landing pads 510. For example, the first contact 521 may be disposed on the first landing pad 511. The second contact 522 may be disposed on the second landing pad 512. The contacts 520 may be arranged in the first direction FD and the second direction SD. The contacts 520 may be disposed to be spaced apart from each other in the first direction FD and the second direction SD. For example, the first contact 521 may be disposed to be spaced apart from the second contact 522 in the first direction FD.

Referring to FIG. 5, in an embodiment, a width w1 of each of the contacts 520 may be constant. For example, the width of the upper surface of each of the contacts 520 may be the same as the width of the lower surface thereof. For example, the side surfaces of the contacts 520 may be substantially perpendicular to the upper surfaces of the landing pads 510 corresponding thereto, respectively. The respective upper surfaces of the contacts 520 may form substantially the same plane. For example, the upper surface of the first contact 521 and the upper surface of the second contact 522 may form substantially the same plane.

The insulating layer 530 and the wirings 540 may be disposed on the contacts 520. The wirings 540 may include a first wiring 541 and a second wiring 542. Each of the wirings 540 may be connected to at least one of the contacts 520. In the illustrated example of FIG. 4 and FIG. 5, the first wiring 541 may be connected to the first contact 521 and the third contact 523. The lower surface of the first wiring 541 may directly contact the upper surface of the first contact 521. The width of each of the wirings 540 in the first direction FD may be greater than the width w1 of each of the contacts 520.

In an embodiment, a second side surface 541b of the first wiring 541 may overlap the first contact 521. The upper surface of the first contact 521 may contact the first wiring 541 and the insulating layer 530. A first side surface 541a of the first wiring 541 may be spaced apart from the side surface of the first contact 521.

The landing pads 510, the contacts 520 and the wirings 540 may include a conductive material such as metal, metal oxide, metal nitride, metal silicide, polysilicon, conductive carbon or a combination thereof. The insulating layer 530 may include silicon oxide, silicon nitride, silicon oxynitride, low-k dielectric, high-k dielectric, or a combination thereof.

In an embodiment, a first spacing between the contacts 520 may be a minimum distance d1 between the side surface of the first contact 521 and the side surface of the second contact 522. For example, the minimum distance d1 between the side surface of the first contact 521 and the side surface of the second contact 522 may be the distance between the upper surface of the first contact 521 and the upper surface of the second contact 522 in the first direction FD or the distance between the lower surface of the first contact 521 and the lower surface of the second contact 522 in the first direction FD.

In an embodiment, the distance between the side surface of the first contact 521 and the side surface of the second contact 522 may be measured after the first contact 521 and the second contact 522 are formed. For example, the distance between the upper surface of the first contact 521 and the upper surface of the second contact 522 may be measured on a planar image that is obtained using a device such as a scanning electron microscope (SEM).

In an embodiment, a second spacing may be the spacing between a side surface among the side surfaces 541a and 541b of the first wiring 541 that is farther away from the first contact 521 and the side surface of the first contact 521. For example, the second spacing may be a minimum distance d2 between the first side surface 541a of the first wiring 541 and the side surface of the first contact 521. Thus, the first side surface 541a of the first wiring 541 is farther away from a side surface of the first contact 521 than the second side surface 541b is from a side surface of the first contact 521.

In an embodiment, the minimum distance d2 between the first side surface 541a of the first wiring 541 and the side surface of the first contact 521 may be measured before the wirings 540 are formed. In an embodiment, the insulating layer 530 may be formed before the wirings 540. The wirings 540 may be formed to be disposed between portions of the insulating layer 530. The side surfaces of the wirings 540 may contact the side surfaces of the portions of the insulating layer 530. For example, the first side surface 541a of the first wiring 541 may contact one side surface of a portion of the insulating layer 530 that neighbors the first wiring 541. The minimum distance d2 between the first side surface 541a of the first wiring 541 and the side surface of the first contact 521 may be the minimum distance between the one side surface of the portion of the insulating layer 530 that contacts the first side surface 541a and the side surface of the first contact 521.

In an embodiment, the minimum distance d2 between the first side surface 541a of the first wiring 541 and the side surface of the first contact 521 may be measured on a planar image that is obtained using a device such as a scanning electron microscope (SEM).

In an embodiment according to the present disclosure, a misalignment between the contacts 520 and the wirings 540 may be determined from a value that is obtained by subtracting the second spacing from the first spacing. For example, a misalignment between the contacts 520 and the wirings 540 may be determined by a value that is obtained by subtracting the minimum distance d2 between the first side surface 541a of the first wiring 541 and the side surface of the first contact 521 from the minimum distance d1 between the side surface of the first contact 521 and the side surface of the second contact 522.

For example, when a value that is obtained by subtracting the minimum distance d2 between the first side surface 541a of the first wiring 541 and the side surface of the first contact 521 from the minimum distance d1 between the side surface of the first contact 521 and the side surface of the second contact 522 is less than or equal to a reference value, it may be determined that the contacts 520 and the wirings 540 are misaligned. For example, the reference value may be 15 nm. In an embodiment, when a value that is obtained by subtracting the minimum distance d2 between the first side surface 541a of the first wiring 541 and the side surface of the first contact 521 from the minimum distance d1 between the side surface of the first contact 521 and the side surface of the second contact 522 is less than the reference value, the first wiring 541 may be short-circuited with the second contact 522. In this instance, because the first wiring 541 is connected to both the first contact 521 and the second contact 522, a defect may occur when transmitting a signal or supplying a voltage through the first wiring 541. Accordingly, in an instance in which a value that is obtained by subtracting the minimum distance d2 between the first side surface 541a of the first wiring 541 and the side surface of the first contact 521 from the minimum distance d1 between the side surface of the first contact 521 and the side surface of the second contact 522 is less than or equal to the reference value, it may be determined that the contacts 520 and the wirings 540 are misaligned.

In an embodiment according to the present disclosure, when a value obtained by subtracting the second spacing from the first spacing is less than or equal to a preset value and the first spacing is within a preset range, it may be determined that a misalignment has occurred between the contacts 520 and the wirings 540 (caused) by the wirings 540. When a value obtained by subtracting the second spacing from the first spacing is less than or equal to the preset value and the first spacing is out of the preset range, it may be determined that a misalignment has occurred between the contacts 520 and the wirings 540 (caused) by the contacts 520 or it may be determined that a misalignment that has occurred has been caused by both the contacts 520 and the wirings 540.

For example, when a value that is obtained by subtracting the minimum distance d2 between the first side surface 541a of the first wiring 541 and the side surface of the first contact 521 from the minimum distance d1 between the side surface of the first contact 521 and the side surface of the second contact 522 is less than or equal to the reference value and the minimum distance d1 between the side surface of the first contact 521 and the side surface of the second contact 522 is within the preset range, it may be determined that a misalignment has occurred between the contacts 520 and the wirings 540 (caused) by the wirings 540. For example, the preset range may be 100 nm to 110 nm. That is to say, when the contacts 520 are properly aligned with the landing pads 510 but the wirings 540 are not properly aligned on the contacts 520, it may be determined that a misalignment has occurred between the contacts 520 and the wirings 540.

In contrast, for example, when a value that is obtained by subtracting the minimum distance d2 between the first side surface 541a of the first wiring 541 and the side surface of the first contact 521 from the minimum distance d1 between the side surface of the first contact 521 and the side surface of the second contact 522 is less than or equal to the reference value and the minimum distance d1 between the side surface of the first contact 521 and the side surface of the second contact 522 is out of the preset range, it may be determined that a misalignment has occurred between the contacts 520 and the wirings 540 caused by the wirings 540 or by both the contacts 520 and the wirings 540.

For example, when the minimum distance d1 between the side surface of the first contact 521 and the side surface of the second contact 522 is less than the preset range, it may be determined that a misalignment has occurred between the contacts 520 and the wirings 540 by the contacts 520. In other words, it may be determined that a misalignment has occurred between the contacts 520 and the wirings 540 because the contacts 520 are not properly aligned on the landing pads 510.

When the minimum distance d1 between the side surface of the first contact 521 and the side surface of the second contact 522 is greater than the preset range, it may be determined that a misalignment has occurred between the contacts 520 and the wirings 540 by both the contacts 520 and the wirings 540. In other words, it may be determined that a misalignment has occurred between the contacts 520 and the wirings 540 because the contacts 520 are not properly aligned on the landing pads 510 and the wirings 540 are also not properly aligned on the contacts 520.

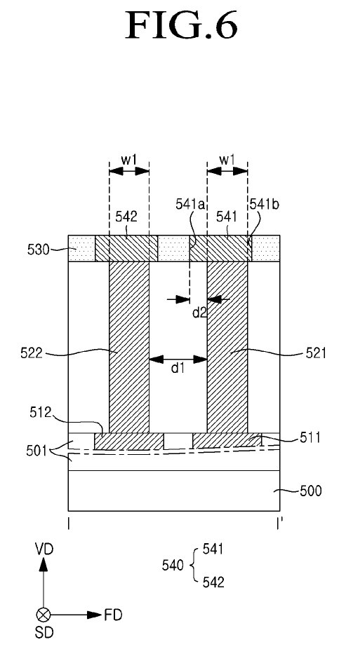

Referring to FIG. 6, each of the contacts 520 may be disposed to be located between side surfaces of each of the wirings 540 in the first direction FD. For example, the first contact 521 may be located between the side surfaces 541a and 541b of the first wiring 541 in the first direction FD. The distance from the first side surface 541a of the first wiring 541 to the side surface of the first contact 521 may be greater than the distance from the second side surface 541b of the first wiring 541 to the side surface of the first contact 521.

A first spacing between the contacts 520 may be measured in the same manner as the first spacing between the contacts 520 described above with reference to FIG. 5. In an embodiment, a second spacing may be a minimum distance d2 between the first side surface 541a among the side surfaces 541a and 541b of the first wiring 541 that is farther away from the first contact 521 and the side surface of the first contact 521. In contrast, when the distance from the first side surface 541a of the first wiring 541 to the side surface of the first contact 521 is less than the distance from the second side surface 541b of the first wiring 541 to the side surface of the first contact 521, the second spacing may be the minimum distance between the second side surface 541b and the side surface of the first contact 521.

In an embodiment, a misalignment between the contacts 520 and the wirings 540 may be determined by a value that is obtained by subtracting the minimum distance d2 between the first side surface 541a farther away from the first contact 521 among the side surfaces of the first wiring 541 and the side surface of the first contact 521 from the minimum distance d1 between the side surface of the first contact 521 and the side surface of the second contact 522.

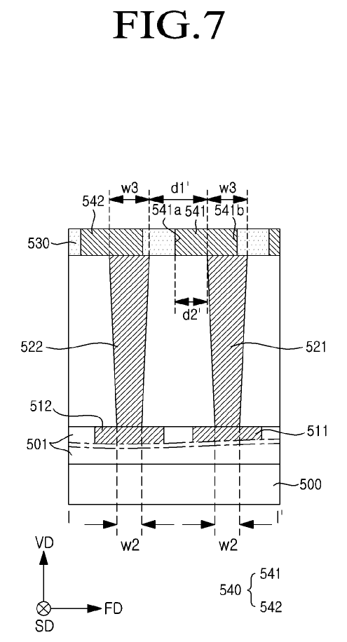

Referring to FIG. 7, a width w3 of the upper surface of each of the contacts 520 may be greater than a width w2 of the lower surface of each of the contacts 520. For example, the width w3 of the upper surface of the first contact 521 may be greater than the width w2 of the lower surface of the first contact 521. The width of each of the contacts 520 may increase as it moves away (i.e., is measured further downward) from the upper surface of the substrate 500.

In an embodiment, a first spacing between the contacts 520 may be the minimum distance between the side surface of the first contact 521 and the side surface of the second contact 522. For example, the first spacing between the contacts 520 may be a distance d1’ in the first direction FD between the upper surface of the first contact 521 and the upper surface of the second contact 522.

In an embodiment, a second spacing may be the spacing between a side surface among the side surfaces 541a and 541b of the first wiring 541 that is farther away from the first contact 521 and the side surface of the first contact 521. For example, the second spacing may be a minimum distance d2’ in the first direction FD between the first side surface 541a of the first wiring 541 and the upper surface of the first contact 521.

In an embodiment, a misalignment between the contacts 520 and the wirings 540 may be determined by a value that is obtained by subtracting the distance d2’ between the first side surface 541a farther away from the first contact 521 among the side surfaces of the first wiring 541 and the side surface of the first contact 521 from the distance d1’ between the upper surface of the first contact 521 and the upper surface of the second contact 522.

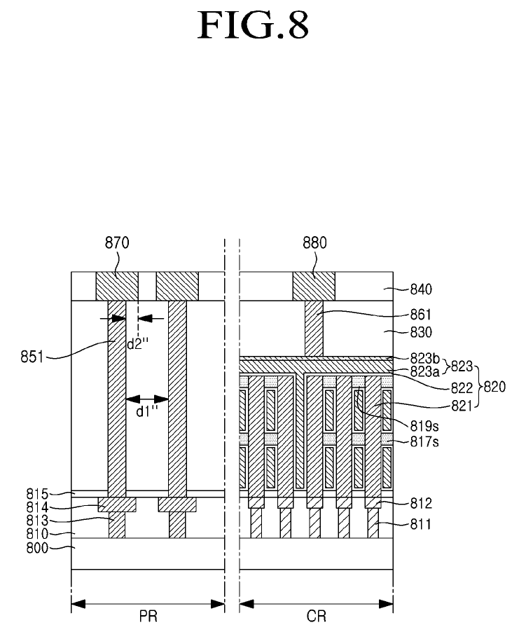

FIG. 8 is a view illustrating an example of a semiconductor device according to embodiments of the present disclosure. The semiconductor device illustrated in FIG. 8 represents an example of a semiconductor device according to the present disclosure, and the semiconductor device according to the present disclosure is not necessarily limited thereto.

Referring to FIG. 8, the semiconductor device according to the embodiments of the present disclosure may include a substrate 800, an interlayer insulating layer 810, a storage node contact 811, a first landing pad 812, a first peripheral contact 813, a second landing pad 814, an etch stop layer 815, a capacitor 820, a first support 817s, a second support 819s, a first insulating layer 830, a second insulating layer 840, a first contact plug 851, a second contact plug 861, a first wiring layer 870, and a second wiring layer 880. The capacitor 820 includes a lower electrode 821, a dielectric layer 822 and an upper electrode 823.

The first contact plug 851 may correspond to each of the contacts 520 described above with reference to FIG. 1 to FIG. 7. The first wiring layer 870 may correspond to the wirings 540 described above with reference to FIG. 1 to FIG. 7.

After first contact plugs 851 are formed, a first distance d1’’ between the first contact plugs 851 may be measured. In an embodiment, the first distance d1'' between the first contact plugs 851 may be the minimum distance from the side surface of one first contact plug 851 to the side surface of another first contact plug 851.

After the second insulating layer 840 is formed on the first contact plugs 851, a second distance d2’’ between the side surface of the first contact plug 851 and one side surface of the first wiring layer 870 may be measured. In an embodiment, the second distance d2’’ may be the minimum distance from a side surface among the side surfaces of the first wiring layer 870 that is farther away from the first contact plug 851 to the side surface of the first contact plug 851 (for example, a minimum distance along a line from the side surface of the first wiring layer 870 to the side surface of the first contact plug 851, as shown in FIG. 8).

According to embodiments of the present disclosure, a misalignment between the first contact plug 851 and the first wiring layer 870 may be determined from a value that is obtained by subtracting the second distance d2'' from the first distance d1''. For example, when a value that is obtained by subtracting the second distance d2'' from the first distance d1'' is less than or equal to a reference value, it may be determined that the first contact plug 851 and the first wiring layer 870 are misaligned. For example, the reference value may be 15 nm.

When a value that is obtained by subtracting the second distance d2'' from the first distance d1'' is less than or equal to the reference value and the first distance d1'' is within a preset range, it may be determined that a misalignment has occurred between the first contact plug 851 and the first wiring layer 870 (caused) by (the positioning or disposition of) the first wiring layer 870. When a value that is obtained by subtracting the second distance d2'' from the first distance d1'' is less than or equal to a preset value and the first distance d1'' is out of the preset range, it may be determined that a misalignment has occurred between the first contact plug 851 and the first wiring layer 870 (was caused) by the first contact plug 851 or it may be determined that a misalignment has occurred between the first contact plug 851 and the first wiring layer 870 caused by both the first contact plug 851 and the first wiring layer 870.

Referring again to FIG. 1 to FIG. 3, a first spacing between the first contact 521 and the second contact 522 neighboring each other may be measured, a second spacing between the side surface of the first wiring 541 connected to the first contact 521 and the side surface of the first contact 521 may be measured, and then, whether there is a misalignment between the contacts 520 and the wirings 540 may be determined from a value that is obtained by subtracting the second spacing from the first spacing.

When a value that is obtained by subtracting the second spacing from the first spacing is equal to or less than a reference value, it may be determined that a misalignment has occurred between the contacts 520 and the wirings 540. In addition, when a value that is obtained by subtracting the second spacing from the first spacing is less than or equal to the reference value, it may be determined that a misalignment has occurred by which elements of the contacts 520 and the wirings 540 depending on whether the first spacing is within a preset range.

According to embodiments of the present disclosure, a misalignment between the contacts 520 and the wirings 540 is determined on the basis of whether the difference between the spacing between the contacts 520 and the spacing between the side surfaces of the wirings 540 connected to the contacts 520 and the contacts 520 is less than or equal to a reference value, and thus, a misalignment that may cause a process defect may be effectively measured. In addition, because the cause of a misalignment is identified differently depending on whether the spacing between the contacts 520 is within a preset range, it is possible to accurately identify which elements of the contacts 520 and the wirings 540 have caused the misalignment to occur.

The above description has been presented to enable any person skilled in the art to make, use and practice the technical features of the present disclosure, and has been provided in the context of a particular application and its requirements as examples. Various modifications, additions and substitutions to the described embodiments will be readily apparent to those skilled in the art, and the principles described herein may be applied to other embodiments and applications without departing from the scope of the present disclosure. In addition, the embodiments disclosed in the present disclosure are not to limit but to explain the technical idea of the present disclosure, and therefore, the scope of the technical idea of the present disclosure is not limited by these embodiments.

What is claimed is:

1. A method of determining a misalignment of a semiconductor device including contacts arranged in a first direction and a second direction intersecting the first direction, and wirings connected to at least one of the contacts and spaced apart from each other in the first direction, the method comprising:
measuring a first spacing between a first contact and a second contact neighboring each other in the first direction, among the contacts;
measuring a second spacing between a side surface of a first wiring among the wirings and a side surface of the first contact, wherein the first wiring is connected to the first contact; and
determining whether there is a misalignment based on the first spacing and the second spacing.

2. The method according to claim 1, wherein the first spacing is a minimum distance between a side surface of the first contact and a side surface of the second contact.

3. The method according to claim 2, wherein the first spacing is a distance in the first direction between an upper surface of the first contact and an upper surface of the second contact.

4. The method according to claim 1, wherein the side surface of the first wiring is a side surface farther away from the first contact in the first direction among side surfaces of the first wiring.

5. The method according to claim 1, wherein the determining whether there is a misalignment comprises:
determining that a misalignment between the contacts and the wirings has occurred when a value obtained by subtracting the second spacing from the first spacing is less than or equal to a preset value.

6. The method according to claim 1, wherein the determining whether there is a misalignment comprises:
determining that a misalignment between the contacts and the wirings has been caused by the wirings when a value obtained by subtracting the second spacing from the first spacing is less than or equal to a preset value and the first spacing is within a preset range.

7. The method according to claim 1, wherein the determining whether there is a misalignment comprises:
determining that a misalignment between the contacts and the wirings has been caused by the contacts or by the contacts and the wirings when a value obtained by subtracting the second spacing from the first spacing is less than or equal to a preset value and the first spacing is out of a preset range.

8. The method according to claim 1, wherein an upper surface of the first contact and an upper surface of the second contact form substantially a same plane.

9. The method according to claim 1, wherein a lower surface of the first wiring directly contacts an upper surface of the first contact.

10. The method according to claim 1, wherein a width of each of the wirings is larger than a width of each of the contacts.

11. A method of determining a misalignment of a semiconductor device including a first contact and a second contact, disposed spaced apart from each other by a first spacing in a first direction and a first wiring connected to the first contact, the first wiring having side surfaces facing each other in the first direction, the method comprising:
measuring a second spacing between a side surface among the side surfaces of the first wiring that is farther away from the first contact and a side surface of the first contact; and
determining whether there is a misalignment based on the first spacing and the second spacing.

12. The method according to claim 11, wherein the first spacing is a minimum distance between the side surface of the first contact and a side surface of the second contact.

13. The method according to claim 11, wherein the first spacing is a distance in the first direction between an upper surface of the first contact and an upper surface of the second contact.

14. The method according to claim 11, wherein the determining whether there is a misalignment comprises:
determining that a misalignment between the contacts and the wirings has occurred when a value obtained by subtracting the second spacing from the first spacing is less than or equal to a preset value.

15. The method according to claim 11, wherein the determining whether there is a misalignment comprises:
determining that a misalignment between the contacts and the wirings has been caused by the first wiring when a value obtained by subtracting the second spacing from the first spacing is less than or equal to a preset value and the first spacing is within a preset range.

16. The method according to claim 11, wherein the determining whether there is a misalignment comprises:
determining that a misalignment between the contacts and the wirings has been caused by the first contact and the second contact or by the first contact, the second contact and the first wiring when a value obtained by subtracting the second spacing from the first spacing is less than or equal to a preset value and the first spacing is out of a preset range.

17. The method according to claim 11, wherein an upper surface of the first contact and an upper surface of the second contact form substantially a same plane.

18. The method according to claim 11, wherein a lower surface of the first wiring directly contacts an upper surface of the first contact.

19. The method according to claim 11, wherein a width of the first wiring is larger than a width of the first contact and the second contact.
